(19) United States
(12) Patent Application Publication
(10) Pub. No.: US 2008/0090348 A1
(43) Pub. Date: Apr. 17, 2008

(54) Gate-assisted silicon-on-insulator on bulk wafer and its application to floating body cell memory and transistors

(76) Inventors: Peter L. D. Chang, Portland, OR (US); Willy Rachmady, Beaverton, OR (US); Seiyon Kim, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/540,987

(22) Filed: Sep. 28, 2006

(51) Int. Cl. H01L 21/8238

(52) U.S. Cl. 438/199

(57) ABSTRACT

Embodiments of methods and apparatus for a gate-assisted silicon-on-insulator on bulk wafer and its application to floating body cells are generally described herein. Other embodiments may be described and claimed.

### FIELD OF THE INVENTION

The field of invention relates generally to the field of semiconductor integrated circuit manufacturing and more specifically, but not exclusively, relates to complementary metal oxide semiconductor (CMOS) devices having a floating body cell with a thin silicon body and a thin backgate oxide on a bulk silicon wafer.

### BACKGROUND INFORMATION

The traditional integrated circuits fabrication process is a series of steps by which a geometric pattern or set of geometric patterns is transformed into an operating integrated circuit (IC). An IC may include super-imposed layers of conducting, insulating, and transistor-forming materials, usually formed on a silicon wafer substrate as groups of transistors and memory cells. Processes have been developed for fabricating integrated circuit devices commonly known as silicon on insulator (SOI) devices. SOI devices are semiconductor devices fabricated within a relatively thin silicon layer that overlies an electrically insulating region formed over a substrate material. This insulating region may include, for example, a layer of SiO₂ deposited or grown over a semiconductor substrate material such as silicon or gallium arsenide. The SOI fabrication process allows circuit devices to be created that are electrically isolated from the underlying substrate.

SOI devices offer several advantages over more conventional semiconductor devices. For example, SOI devices may have lower power consumption requirements than other types of devices that perform similar tasks. SOI devices may also have lower parasitic capacitances than non-SOI devices. This translates into faster switching times for the resulting circuits. Also, the phenomenon of latchup, which is often exhibited by CMOS devices, may be avoided when circuit devices are manufactured using SOI fabrication processes. Moreover, the higher packing densities of floating body memory cells allowed by SOI design drive circuit designers to incorporate the floating body cells (FBC) in dedicated memory devices as well as in embedded memory.

### BRIEF DESCRIPTION OF THE DRAWINGS

The present invention is illustrated by way of example and not limitation in the figures of the accompanying drawings, in which

FIG. 1 illustrates a top view of a semiconductor device with a memory cell area and a logic area.

FIG. 2 is a cross-sectional view of FIG. 1 taken through section line A-A illustrating a substrate, a region of doped silicon, a silicon germanium region, and a body of silicon adjacent to an isolation region.

FIG. 3 is a cross-sectional view of FIG. 1 taken through section line B-B illustrating a gate on a substrate, a region of doped silicon, a silicon germanium region, and a body of silicon.

FIG. 4 illustrates the structure of FIG. 3 further including an etch buffer layer on the gate and the body of silicon.

FIG. 5 illustrates the structure of FIG. 4 after anisotropically etching the etch buffer layer.

FIG. 6 illustrates the structure of FIG. 2 after anisotropically etching a top portion of the isolation region.

FIG. 7 illustrates the structure of FIG. 6 after etching the silicon germanium region.

FIG. 8 illustrates the structure of FIG. 7 after forming a backgate below the body of silicon.

FIG. 9 illustrates the structure of FIG. 5 after forming a spacer layer on the gate and the body of silicon.

FIG. 10 illustrates the structure of FIG. 9 after anisotropically etching the spacer layer.

FIG. 11 illustrates a three-dimensional embodiment of a floating body cell on a bulk wafer.

FIG. 12 is a flowchart describing an embodiment of a fabrication process used to form a tightly controlled body of silicon and backgate for a floating body cell on a bulk wafer.

FIG. 13 is a flowchart describing an alternative embodiment of a fabrication process used to form a tightly controlled body of silicon and backgate for a floating body cell on a bulk wafer.

### DETAILED DESCRIPTION

In various embodiments, an apparatus and methods relating to a gate-assisted silicon on insulator on a bulk wafer and its application to floating body cell memory and transistors are described in various embodiments. However, one skilled in the relevant art will recognize that the various embodiments may be practiced without one or more of the specific details, or with other replacement and/or additional methods, materials, or components. In other instances, wellknown structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

There is a general need for forming a tightly controlled thin silicon body and backgate for a floating body cell for transistor and memory devices on a bulk wafer. By forming a well controlled silicon body and backgate on a bulk wafer, potential leakage paths may be avoided while minimizing related manufacturing costs. One embodiment of a method for fabricating a floating body cell includes forming a body of silicon on a silicon germanium region and adjacent to an isolation region. A gate is formed on the body of silicon and an etch buffer is formed on the gate. A top portion of the isolation region is etched to expose the silicon germanium region. The silicon germanium region is etched and a backgate is formed below the body of silicon. A spacer is formed on the etch buffer on the gate.

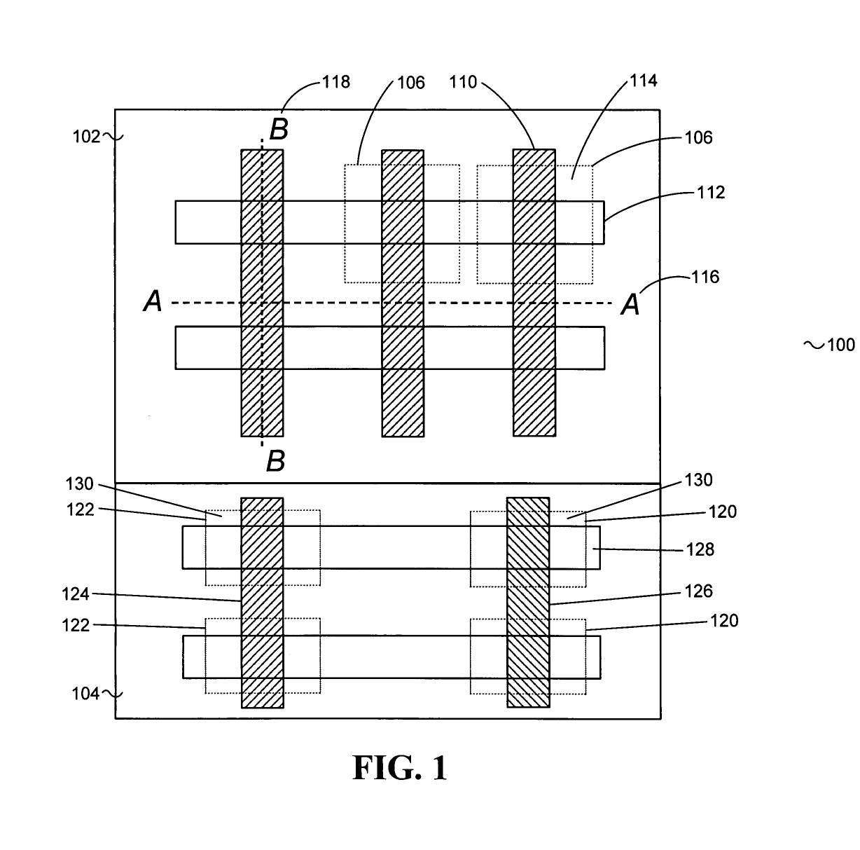

The illustration in FIG. 1 is a top view of a semiconductor device 100, comprising an area of memory cells 102 connected to a logic area 104. Alternatively, in another embodiment, the area of memory cells 102 is physically separate from the logic area 104. The area of memory cells 102 comprises a plurality of floating-body memory cells 106, each containing a region of positively doped silicon 110, a gate 112, and an isolation region 114. In another embodiment, each memory cell 106 comprises a region of negatively doped silicon 110, a gate 112, and an isolation region 114. Section line A-A 116 represents a plane that will be later used to illustrate the underlying structure of the doped silicon 110 and the isolation layer 114. Section line B-B 118 represents a plane that will be later used to illustrate the underlying structure of the gate 112 and the doped silicon 110.

The logic area 104 comprises a plurality of p-channel metal oxide semiconductor (PMOS) field effect transistors 120 and a plurality of n-channel metal oxide semiconductor (NMOS) field effect transistors 122. In one embodiment, each PMOS field effect transistor 120 comprises a region of silicon with n-type dopant 126, a gate 128, and an isolation layer 130, such as an isolation oxide. Further, each NMOS field effect transistor 122 comprises a region of silicon with p-type dopant 124, a gate 128, and an isolation layer 130. In one embodiment, the PMOS field effect transistor 120 and the NMOS field effect transistor 122 is planar in construction using methods commonly known to one skilled in the art.

In another embodiment, the PMOS field effect transistor 120 and the NMOS field effect transistor 122 are three-dimensional multi-gate transistors as described in United States Patent Publication No. US 2005/0156171 A1 (Jul. 21, 2005). The publication describes the fabrication of a three-dimensional transistor known as a tri-gate transistor, which consists of three gates. As described therein, a semiconductor body having a top surface and a first a second laterally opposite sidewalls are formed on an insulating substrate. A gate electrode and a gate dielectric are formed on the top surface of the semiconductor body and on the first and second laterally opposite sidewalls of the semiconductor body. A pair of source and drain regions are formed in the semiconductor body on opposite sides of the gate electrode. In a third embodiment, the PMOS field effect transistor 120 and the NMOS field effect transistor (FET) 122 each comprise two gates, commonly known as a dual-gate field effect transistor or a FIN-FET.

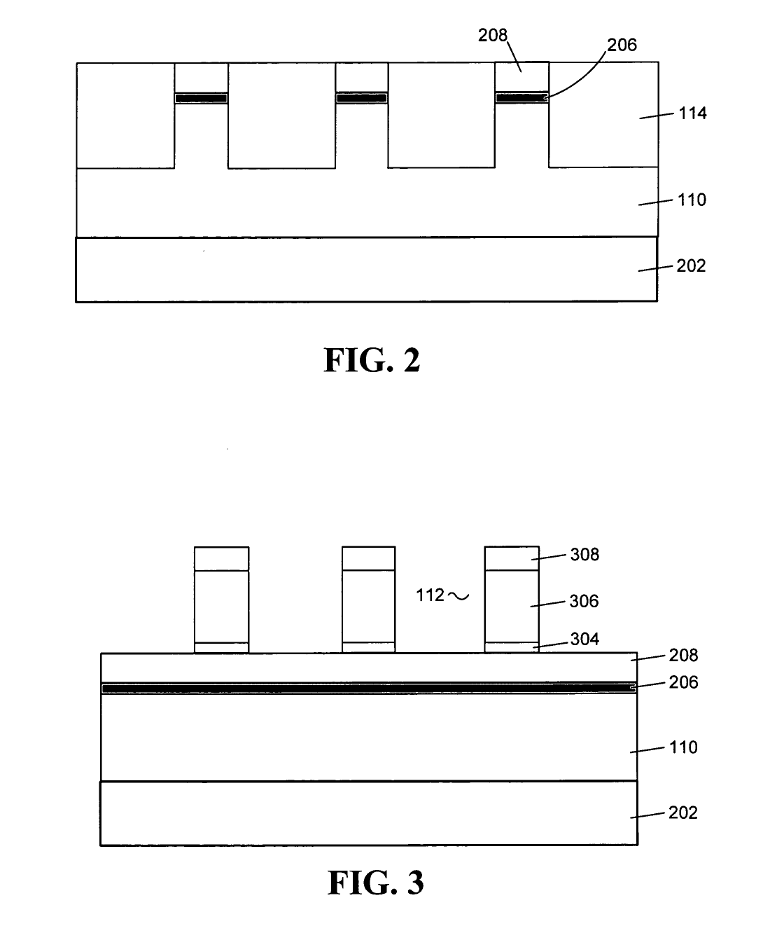

FIG. 2 is a cross-sectional view of an underlying structure found in FIG. 1 taken through section line A-A 116. The underlying structure comprises a substrate 202. The substrate 202 may comprise any material that may serve as a foundation upon which a semiconductor device may be built, such as a monocrystalline silicon wafer or a silicon-on-insulator (SOI) wafer. In this embodiment, substrate 202 is a monocrystalline silicon substrate with an overlying region of doped silicon 110. The doped silicon 110 may be doped using an ion implantation process followed by a thermal anneal process or the doped silicon 110 may be formed using an epitaxial process. The doped silicon 110 is shaped into a three-dimensional structure through a series of lithography and etch processes commonly known to one skilled in the art.

An isolation layer 114 is deposited on the doped silicon 110 using chemical vapor deposition, spin-on deposition, or plasma assisted chemical vapor deposition. A silicon germanium region 206 is formed on the exposed areas of the doped silicon 110 using an epitaxial process on an area of memory cells 102. The epitaxial process is used in this embodiment so that the thickness of the silicon germanium region 206 can be tightly controlled down to a thickness of 20 nanometers (nm) or less. The silicon germanium region 206 may be nonstoichiometric while containing only a fraction of germanium, such as Si_{0.8}Ge_{0.2}. A body of silicon 208 may be formed on the top of the silicon germanium region 206, also using the accuracy and precision provided by the epitaxial process. In one embodiment, the thickness of the silicon germanium layer 206 may be less than 5 nm.

FIG. 3 is a cross-sectional view of an underlying structure found in FIG. 1 taken through section line B-B 118. The underlying structure comprises a substrate 202, a region of doped silicon 110, a silicon germanium region 206, a body of silicon 208, and a gate 112 comprising a gate dielectric 304 and a gate body 306. A hard-mask cap 308 may be formed on the gate body 306 to protect the top of the gate body 306 during subsequent processing. The gate dielectric 304 may be silicon dioxide or alternatively, a high-k dielectric layer such as lanthanum oxide, tantalum oxide, titanium oxide, hafnium oxide, zirconium oxide, lead-zirconate-titanate (PZT), barium-strontium-titanate (BST), or aluminum oxide. In one embodiment, the high-k dielectric layer is between 15 angstroms and 30 angstroms in thickness. The gate body 306 may be comprised of one or more gate materials including polysilicon and a workfunction metal. A workfunction metal is a metal with a known work function, which is an inherent characteristic of a metal such as tungsten, tantalum, titanium, and/or nitrides and alloys thereof. The hard-mask cap 308 may be one or more of silicon nitride, silicon oxynitride, and carbon doped nitride.

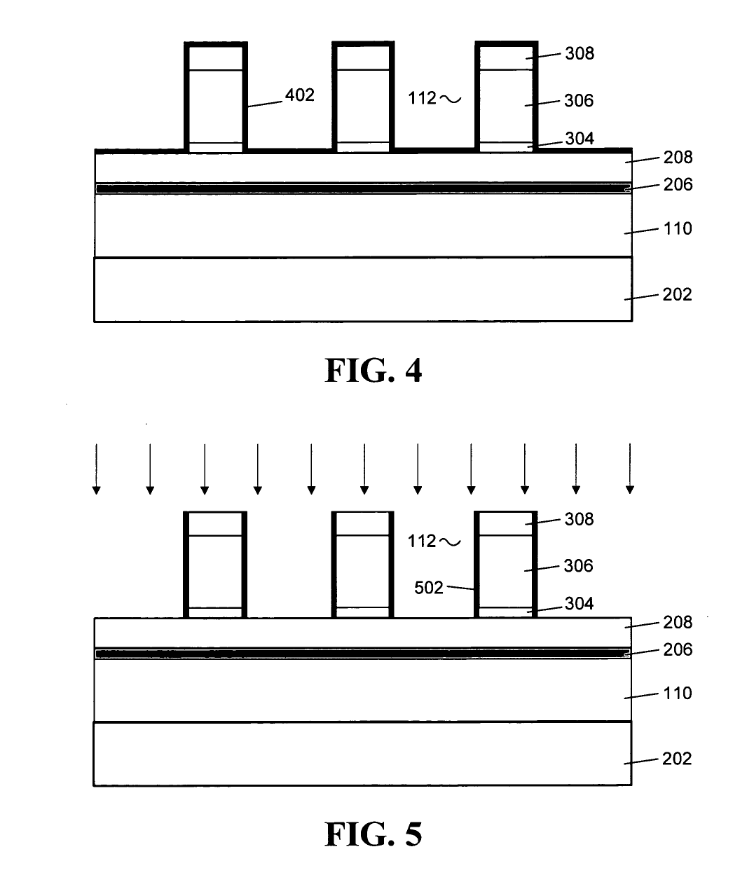

FIG. 4 illustrates the structure of FIG. 3 further including an etch buffer layer 402 on the gate 112 and the body of silicon 208. The etch buffer layer 402 may be comprised of at least one of silicon nitride, silicon oxynitride, and carbon doped nitride. The etch buffer layer 402 may be deposited across the entire wafer and later eroded to expose the body of silicon 208, as shown in FIG. 5, while leaving an etch buffer 502 on a side of the gate 112.

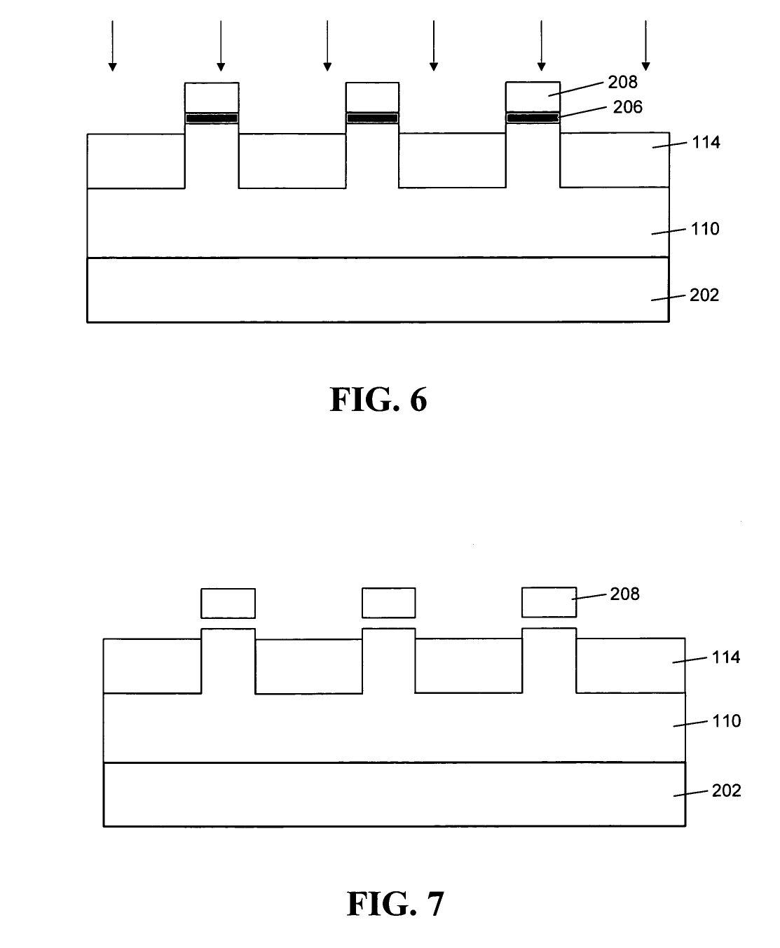

FIG. 6 illustrates the structure of FIG. 2 after anisotropically etching a top portion of the isolation region 114, which is at least one of field oxide and silicon nitride. By etching anisotropically, an etch rate in the direction normal to a surface is much higher than in a direction parallel to the surface. The portion of the isolation region 114 may be eroded with a typical dry etch process using sulfur hexafluoride (SF6), oxygen (O2), carbon monoxide (CO), and argon (Ar), or a fluorinated hydrocarbon (CHxFy) gas in a magnetically enhanced reactive ion etch (MERIE) or an electron cyclotron resonance (ECR) chamber or tool.

The silicon germanium region 206 is etched, as shown in FIG. 7, using at least one of an isotropic fluorine-based wet etch or a dry-etch process, a fluorine-based wet etchant comprising a solution of nitric acid (HNO3), hydrofluoric acid (HF), acetic acid (CH3COOH), and water (H2O). In one embodiment, the wet etchant solution may comprise 100 to 150 parts HNO3, 0.25 to 2 parts HF, 200 to 300 parts CH3COOH, and 0 to 50 parts H2O.

By etching isotropically, an etch rate in the direction normal to a surface is substantially the same as in a direction parallel to the surface. The silicon layer 208 may be supported by the gate 304 while the silicon germanium region is etched, thereby creating a void beneath the body of silicon 208. In another embodiment, the silicon germanium region may be exposed by masking the silicon layer 208 and etching a trench in the body of silicon 208, the silicon germanium region 206, and optionally the doped silicon 110 using methods known to those skilled in the art. The masking of the silicon layer 208 may be accomplished with a sacrificial spacer self-aligned to the gate 304. The sacrificial spacer can also serve as the etch buffer 502 as shown in FIG. 5.

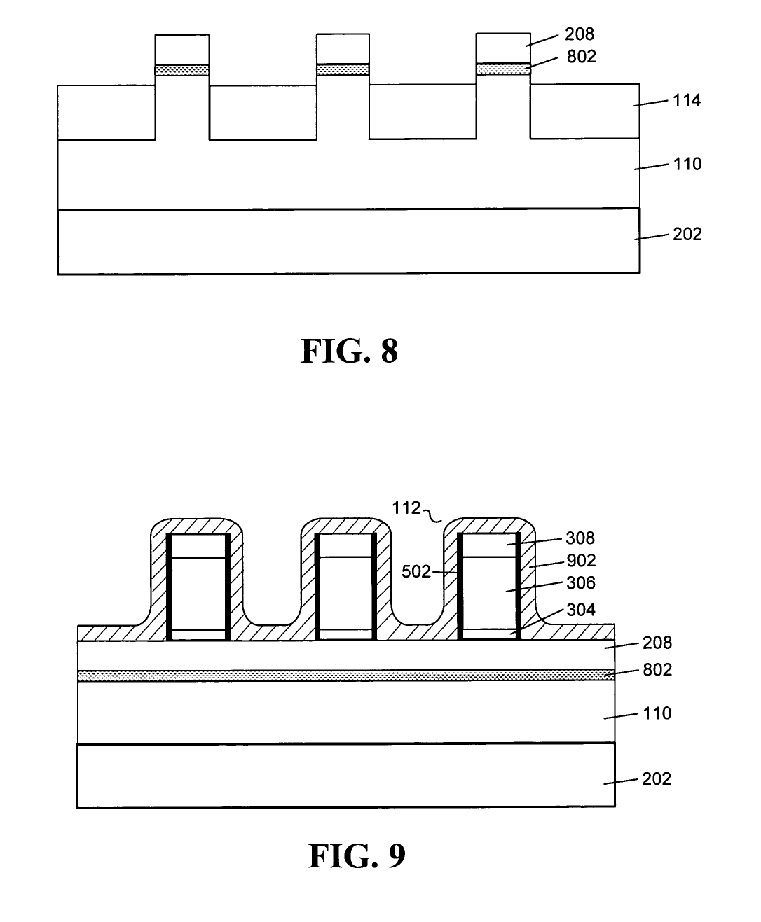

FIG. 8 illustrates the structure of FIG. 7 after forming a backgate 802 below the body of silicon 208. The backgate 802 is deposited or grown in the region between the doped silicon 110 and the body of silicon 208 using a high temperature oxidation process or a chemical vapor deposition process. The backgate 802 may be at least one of silicon nitride and silicon dioxide. In one embodiment where the backgate 802 is deposited, the materials over the wafer may be removed with a wet etch or dry etch to expose the silicon 208 for subsequent process. In another embodiment with a thin backgate 802, the deposited materials may be left on the wafer and removed later during the etch process for forming spacer layer 1002 as described in the following paragraph. In one embodiment, the sacrificial spacer may be removed after the deposited backgate materials are removed.

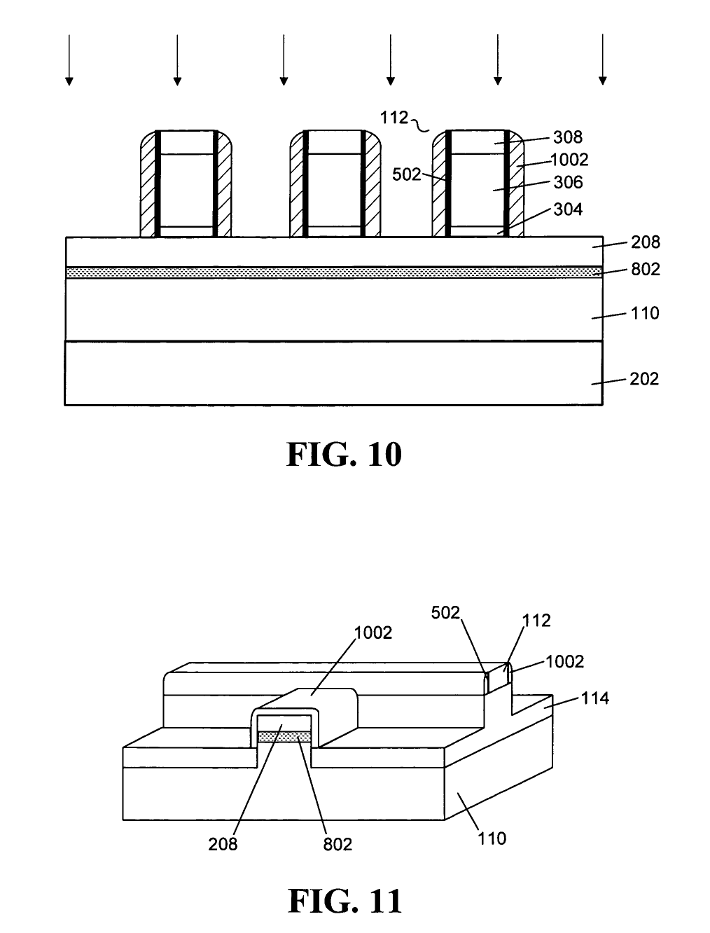

FIG. 9 illustrates the structure of FIG. 5 after forming a spacer layer 902 on the gate 112 and the body of silicon 208. The spacer layer 902 may be comprised of at least one of silicon nitride, carbon doped silicon nitride, and silicon oxynitride. The spacer layer 902 is later eroded to expose the body of silicon 208 and to form a spacer 1002 on a side of the gate 112, as shown in FIG. 10. The spacer 1002 may be eroded anisotropically using sulfur hexafluoride (SF6), oxygen (O2), carbon monoxide (CO), and argon (Ar), or a fluorinated hydrocarbon (CHxFy) gas in a magnetically enhanced reactive ion etch (MERIE) or an electron cyclotron resonance (ECR) chamber or tool. In one embodiment where a trench is etched in the body of silicon 208 with a sacrificial spacer, the trench may be filled and planarized by the spacer layer 902 if a proper thickness is chosen for a given distance between the gates. For example, the trench opening is 40 nm for a 60 nm thick sacrificial spacer between 2 gates 160 nm apart. The 40 nm trench can be filled and planarized by a 25 nm thick spacer layer 902. The trench will remained filled post the spacer etch and provide isolation between source drain and the substrate 202. After the removal of the sacrificial spacer, a 35 nm long diffusion can be exposed and raised source drain structures can be formed with epitaxial silicon growth.

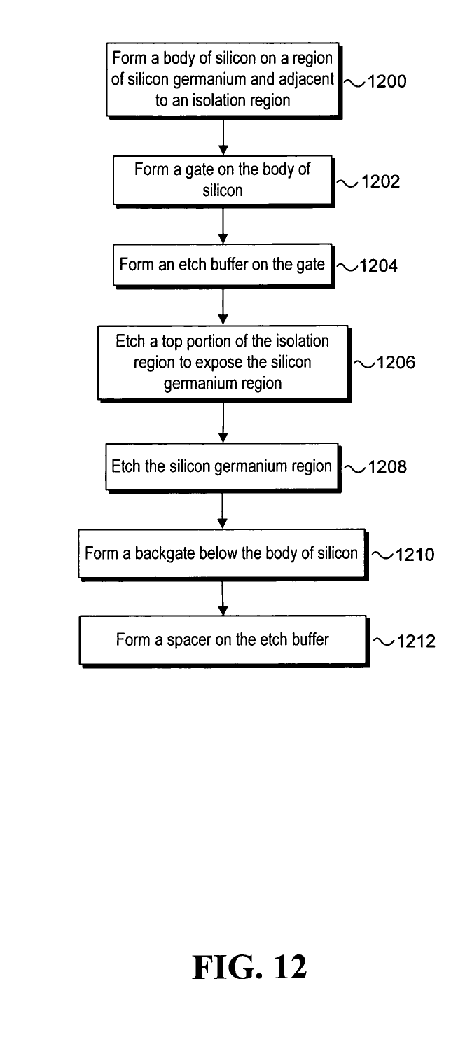

FIG. 11 illustrates a three-dimensional embodiment of a floating body cell on a bulk wafer as described in FIG. 2 through FIG. 10. FIG. 12 is a flowchart describing an embodiment of a fabrication process used to form a tightly controlled body of silicon 208 and backgate 802 for a floating body memory cell 106 on a bulk wafer, as illustrated in FIG. 1 through FIG. 10. In element 1200, a body of silicon 208 is formed on a silicon germanium region 206 and adjacent to an isolation region 114. The body of silicon 208 is formed using an epitaxial process on top of an epitaxially grown silicon germanium region 206. In element 1202, a gate 112 comprising a gate dielectric 304 and a gate body 306, is formed on the body of silicon 208. A hard-mask cap 308 may be formed on the gate body 306 to protect the top of the gate body 306 during subsequent processing. In element 1204, an etch buffer layer 402 is formed on the gate stack and later eroded to expose the body of silicon 208 while leaving an etch buffer 502 on the gate 112. A top portion of the isolation region 114, such as a field oxide layer, is eroded to expose the silicon germanium region 206 (element 1206). In element 1208, the silicon germanium region 206 is etched using at least one of a fluorine-based wet etch and a dry-etch process.

A backgate 802 is formed below the body of silicon 208 using at least one of a high thermal oxidation process, a nitridation process, and a chemical vapor deposition process (element 1210) or an atomic layer deposition (ALD) process. In element 1212, a spacer layer 902 is formed and later eroded to expose the body of silicon 208 while leaving a spacer 1002 on a gate 112.

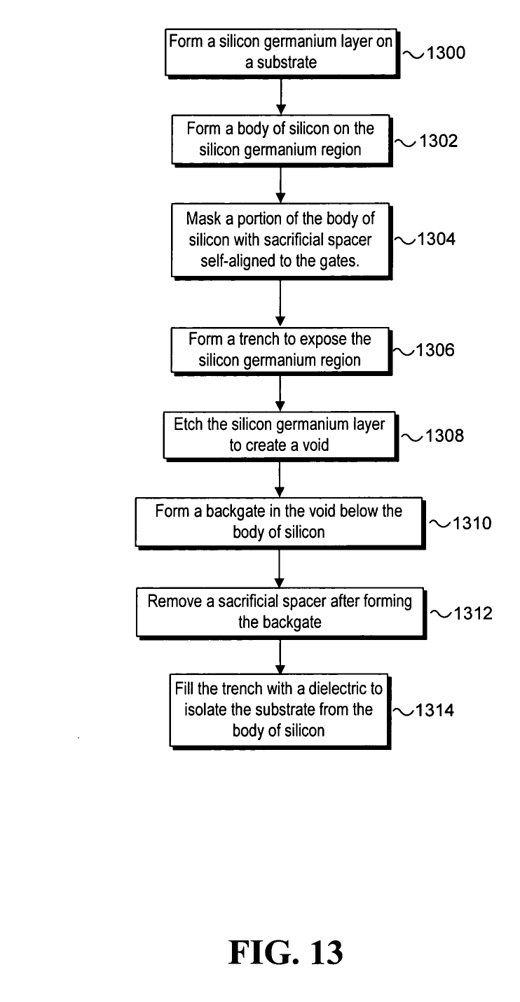

FIG. 13 is a flowchart describing an alternative embodiment of a fabrication process used to form a tightly controlled body of silicon 208 and a backgate 206 for a floating body memory cell 106 on a bulk wafer. In element 1300, a silicon germanium region 206 is formed on a substrate 202 using an epitaxial process. A body of silicon 208 is formed on the silicon germanium region 206 (element 1302) also using an epitaxial process. The body of silicon 208 is then masked, using methods known to those skilled in the art, to protect a gate 112 while leaving portions of the body of silicon 208 exposed (element 1304). The body of silicon 208 may be eroded to create a via or trench to expose the silicon germanium region 206 (element 1306). In element 1308, the silicon germanium region 206 is etched to create a very thin and uniform void below the body of silicon 208. A backgate 802 is formed in the void below the body of silicon 208 using a high temperature oxidation process, a nitridation process, or a chemical vapor deposition process (element 1310). A sacrificial spacer is removed (element 1312) after the backgate 802 is formed. The trench is filled with a dielectric filler, which is at least one of a silicon nitride, carbon doped silicon nitride, and silicon dioxide to isolate the substrate 202 from the body of silicon 208 (element 1314).

Several embodiments for forming a tightly controlled thin silicon body and backgate for a floating body cell on a bulk wafer are generally described herein. The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method for fabricating a floating body cell comprising:
forming a body of silicon on a silicon germanium region and adjacent to an isolation region;
forming a gate on the body of silicon;
forming an etch buffer on the gate;
etching a top portion of the isolation region to expose the silicon germanium region;
etching the silicon germanium region;
forming a backgate below the body of silicon; and
forming a spacer on the etch buffer.

2. The method of claim 1, wherein forming the silicon germanium region using an epitaxial process.

3. The method of claim 1, wherein the gate comprises a gate dielectric and a gate body.

4. The method of claim 3, wherein the gate dielectric is selected from the group consisting of silicon dioxide, lanthanum oxide, tantalum oxide, titanium oxide, hafnium oxide, zirconium oxide, lead-zirconate-titanate, barium-strontium-titanate, and aluminum oxide.

5. The method of claim 3, wherein the gate body is selected from the group consisting of polysilicon, tungsten, tantalum, titanium and/or nitrides and alloys thereof.

6. The method of claim 1, wherein the etch buffer is selected from the group consisting of silicon nitride, silicon oxy-nitride, and carbon doped nitride.

7. The method of claim 1, wherein the isolation region is at least one of field oxide and silicon nitride.

8. The method of claim 1, wherein etching the silicon germanium region includes using a fluorine-based wet etch process.

9. The method of claim 1, wherein the backgate is selected from the group consisting of silicon dioxide and silicon nitride.

10. The method of claim 1, wherein the spacer is selected from the group consisting of silicon nitride, silicon oxy-nitride, and carbon doped nitride.

11. A method to form a semiconductor device, comprising:
forming a silicon germanium region on a substrate;
forming a body of silicon on the silicon germanium region;
masking a portion of the body of silicon;
forming a trench to expose the silicon germanium region;
etching the silicon germanium region;
forming a backgate below the body of silicon; and
depositing a dielectric filler in the trench to isolate the substrate from the body of silicon.

12. The method of claim 11, wherein etching the silicon germanium layer includes using a fluorine-based wet etch process.

13. The method of claim 11, wherein the backgate is selected from the group consisting of silicon dioxide and silicon nitride.

14. The method of claim 11, wherein the dielectric filler is selected from the group consisting of silicon nitride, silicon oxy-nitride, and carbon doped nitride.

15. A semiconductor device comprising:
a substrate with a logic area comprising a plurality of multi-gate transistors and an area of memory cells comprising a plurality of floating-body memory cells, the multi-gate transistors and the floating-body memory cells including:
a backgate less than 20 nanometers in thickness;
a body of silicon on the backgate; and
a gate on the body of silicon.

16. The device of claim 15, wherein the multi-gate transistor is a dual-gate transistor or a tri-gate transistor.

17. The device of claim 15, wherein the backgate is selected from the group consisting of silicon dioxide and silicon nitride.

18. The device of claim 15, wherein the gate comprises a gate dielectric and a gate body.

19. The device of claim 18, wherein the gate dielectric is selected from the group consisting of silicon dioxide, lanthanum oxide, tantalum oxide, titanium oxide, hafnium oxide, zirconium oxide, lead-zirconate-titanate, barium-strontium-titanate, and aluminum oxide.

20. The device of claim 18, wherein the gate body is selected from the group consisting of polysilicon, tungsten, tantalum, titanium and/or nitrides and alloys thereof.
